(19) United States
(12) Patent Application Publication
(10) Pub. No.: US 2026/0026298 A1
(43) Pub. Date: Jan. 22, 2026

(54) SUBSTRATE PROCESSING APPARATUS AND ABNORMALITY DETECTING METHOD

(71) Applicant: Tokyo Electron Limited, Tokyo (JP)

(72) Inventors: Suguen LEE, Kumamoto (JP); Tetsuya SAKAZAKI, Kumamoto (JP)

(73) Assignee: Tokyo Electron Limited, Tokyo (JP)

(21) Appl. No.: 19/256,200

(22) Filed: Jul. 1, 2025

(30) Foreign Application Priority Data
Jul. 18, 2024 (JP) 2024-114570

(51) Int. Cl. H01L 21/67

(52) U.S. Cl. CPC H01L 21/67288; H01L 21/67051

(57) ABSTRACT

A substrate processing apparatus includes a chamber, a nozzle, a measurement unit, a flow-path opening/closing unit, and a controller. The chamber is capable of housing therein a substrate. The nozzle is arranged in the chamber to supply processing liquid towards the substrate. The measurement unit projects light to the substrate to measure an intensity of reflected light from the substrate. The flow-path opening/closing unit opens/closes a supply flow path of the processing liquid to the nozzle. The controller is configured to output an opening signal and a closing signal to the flow-path opening/closing unit. The controller is further configured to detect abnormality related to leakage of the processing liquid from the nozzle based on the intensity of reflected light that is measured by the measurement unit after an output of the closing signal.

### CROSS-REFERENCE TO RELATED APPLICATION

This application is based upon and claims the benefit of priority of the prior Japanese Patent Application No. 2024-114570, filed on Jul. 18, 2024, the entire contents of which are incorporated herein by reference.

### FIELD

Exemplary embodiments disclosed herein relate to a substrate processing apparatus and an abnormality detecting method.

### BACKGROUND

Processes included in semiconductor manufacturing process include a liquid processing process for supplying processing liquid to a substrate, such as a semiconductor wafer and a glass substrate, so as to process the substrate.

The liquid processing process includes arranging a nozzle above a substrate, which is connected to a processing liquid supply source via a supply route, and discharging, from the nozzle, processing liquid supplied from the processing liquid supply source. A valve is arranged on a supply route, and the valve is opened/closed so as to change a discharging state of the processing liquid discharged from the nozzle.

There has been known a technology for monitoring abnormality related to leakage of processing liquid from a nozzle on the basis of a captured image that is acquired by an infrared camara (see WO 2019/146456, for example).

A substrate processing apparatus according to one aspect of embodiments includes a chamber, a nozzle, a measurement unit, a flow-path opening/closing unit, and a controller. The chamber is capable of housing therein a substrate. The nozzle is arranged in the chamber to supply processing liquid towards the substrate. The measurement unit projects light to the substrate to measure an intensity of reflected light from the substrate. The flow-path opening/closing unit opens/closes a supply flow path of the processing liquid to the nozzle. The controller is configured to output an opening signal and a closing signal to the flow-path opening/closing unit, the opening signal causing the flow-path opening/closing unit to execute an opening operation for opening the supply flow path, and the closing signal causing the flow-path opening/closing unit to execute a closing operation for closing the supply flow path. The controller that is further configured to detect abnormality related to leakage of the processing liquid from the nozzle based on the intensity of reflected light that is measured by the measurement unit after an output of the closing signal.

### SUMMARY

### Brief Description of Drawings

FIG. 1 is a diagram illustrating a configuration of a substrate processing system according to a first embodiment;

FIG. 2 is a diagram illustrating a configuration of a process unit according to the first embodiment;

FIG. 3 is a diagram illustrating a configuration example of a processing fluid supply unit according to the first embodiment;

FIG. 4 is a block diagram illustrating a configuration example of a control device according to the first embodiment;

FIG. 5 is a diagram illustrating an execution timing of a monitoring process according to the first embodiment;

FIG. 6 is a diagram illustrating one example of measurement result of a measurement unit in a case where leakage of processing liquid from a nozzle has not occurred;

FIG. 7 is a diagram illustrating one example of measurement result of the measurement unit in a case where leakage of the processing liquid from the nozzle has occurred;

FIG. 8 is a flowchart illustrating a procedure for the monitoring process according to the first embodiment;

FIG. 9 is a diagram illustrating an acquisition timing of a reference intensity and an execution timing of a monitoring process according to a second embodiment; and

FIG. 10 is a diagram illustrating a configuration example of a processing fluid supply unit according to a third embodiment.

### DESCRIPTION OF EMBODIMENTS

Hereinafter, modes (hereinafter, may be referred to as “embodiments”) for implementing a substrate processing apparatus and an abnormality detecting method according to the present disclosure will be described in detail with reference to the accompanying drawings. In addition, the illustrative embodiments disclosed below are not intended to limit the disclosed technology. Note that any of the embodiments can be appropriately combined with each other within a consistency range. Hereinafter, the same reference symbol is provided to the same part in the following embodiments so as to omit duplicated explanation.

### First Embodiment

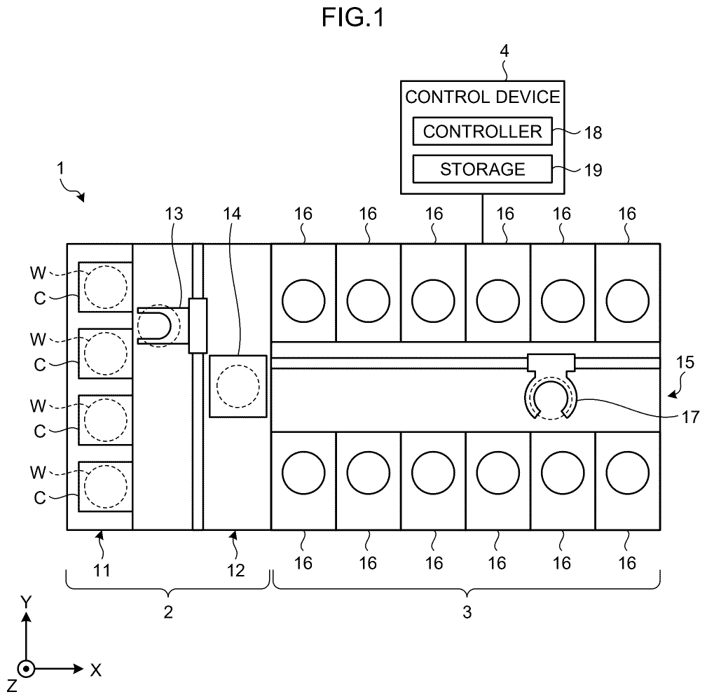

FIG. 1 is a diagram illustrating a configuration of a substrate processing system according to a first embodiment. For convenience of explanation, in the following drawings to be mentioned later, an X-axis, a Y-axis, and a Z-axis are defined, and further the positive Z-axis direction is defined as a vertical upward direction.

As illustrated in FIG. 1, a substrate processing system 1 (one example of substrate processing apparatus) includes a carry-in/out station 2 and a processing station 3. The carry-in/out station 2 and the processing station 3 are arranged adjacently to each other.

The carry-in/out station 2 includes a carrier placing section 11 and a transfer section 12. A plurality of carriers C is placed in the carrier placing section 11, each of which accommodates therein a plurality of substrates in a horizontal state, and the substrates are semiconductor wafers (hereinafter, may be referred to as wafers W, one example of substrates) in the present embodiment.

The transfer section 12 is arranged adjacently to the carrier placing section 11, and further includes therein a substrate transfer device 13 and a delivery unit 14. The substrate transfer device 13 includes a wafer holding mechanism configured to hold the wafer W. The substrate transfer device 13 is capable of moving in a horizontal direction and a vertical direction, and turning around a vertical axis so as to transfer the wafer W between the carrier C and the delivery unit 14 by using the wafer holding mechanism.

The processing station 3 is arranged adjacently to the transfer section 12. The processing station 3 includes a transfer section 15 and a plurality of process units 16. The plurality of process units 16 is aligned on both sides of the transfer section 15.

The transfer section 15 includes therein a substrate transfer device 17. The substrate transfer device 17 includes a wafer holding mechanism configured to hold the wafer W. The substrate transfer device 17 is capable of moving in a horizontal direction and a vertical direction, and turning around a vertical axis so as to transfer the wafer W between the delivery unit 14 and the process unit 16 by using a wafer holding mechanism.

The process unit 16 executes predetermined substrate processing on the wafer W having been transferred by the substrate transfer device 17.

The substrate processing system 1 includes a control device 4. The control device 4 is a computer, for example, so as to include a controller 18 and a storage 19. The storage 19 stores therein programs that control various processes to be executed in the substrate processing system 1. The controller 18 reads and executes a program stored in the storage 19 so as to control operation of the substrate processing system 1.

Note that the above-mentioned program may be one that is recorded in a computer-readable storage medium, and further may be installed in the storage 19 of the control device 4 from the storage medium. For example, a hard disk (HD), a flexible disk (FD), a compact disk (CD), a magnet-optical disk (MO), a memory card, or the like may be employed for the computer-readable storage medium.

In the substrate processing system 1 configured as described above, the substrate transfer device 13 of the carry-in/out station 2 first takes out the wafer W from the carrier C placed in the carrier placing section 11, and further places the taken-out wafer W on the delivery unit 14. The wafer W placed on the delivery unit 14 is taken out from the delivery unit 14 by the substrate transfer device 17 of the processing station 3, and further is carried into the process unit 16.

The wafer W carried into the process unit 16 is processed by the process unit 16, and then is carried out of the process unit 16 by the substrate transfer device 17 to be placed on the delivery unit 14. The processed wafer W placed on the delivery unit 14 is returned to the carrier C of the carrier placing section 11 by the substrate transfer device 13.

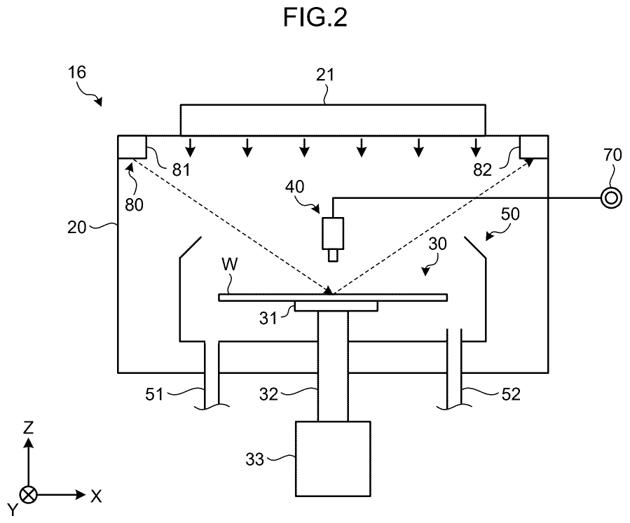

Next, the process unit 16 will be explained with reference to FIG. 2. FIG. 2 is a diagram illustrating a configuration of the process unit 16 according to the first embodiment.

As illustrated in FIG. 2, the process unit 16 includes a chamber 20, a substrate holding mechanism 30, a processing fluid supply unit 40, and a recovery cup 50.

The chamber 20 accommodates therein the substrate holding mechanism 30, the processing fluid supply unit 40, and the recovery cup 50. A Fan Filter Unit (FFU) 21 is arranged in a ceiling portion of the chamber 20. The FFU 21 forms downflow in the chamber 20.

The substrate holding mechanism 30 includes a holding unit 31, a supporting unit 32, and a drive unit 33. The holding unit 31 horizontally holds the wafer W. The supporting unit 32 is a member extending in a vertical direction, a bottom end thereof is supported by the drive unit 33 to be rotatable, and a leading end thereof horizontally supports the holding unit 31. The drive unit 33 rotates the supporting unit 32 around a vertical axis. The above-mentioned substrate holding mechanism 30 causes the drive unit 33 to rotate the supporting unit 32 so as to rotate the holding unit 31 supported by the supporting unit 32, and further rotates the wafer W held by the holding unit 31.

The processing fluid supply unit 40 supplies process fluid to the wafer W. The processing fluid supply unit 40 is connected to a processing fluid supply source 70.

The recovery cup 50 is arranged to surround the holding unit 31, so as to collect processing liquid splashing from the wafer W by rotation of the holding unit 31. A drain port 51 is formed in a bottom portion of the recovery cup 50, and processing liquid collected by the recovery cup 50 is discharged from the above-mentioned drain port 51 to the outside of the process unit 16. Additionally, an exhaust port 52 is formed in a bottom portion of the recovery cup 50, which discharges gas supplied from the FFU 21 to the outside of the process unit 16.

The process unit 16 further includes a measurement unit 80. The measurement unit 80 arranged on an inner surface of the chamber 20. The measurement unit 80 includes a light projecting unit 81 and a light receiving unit 82 so as to project light to the wafer W, and further to measure an intensity of reflected light from the wafer W. Measurement result of the measurement unit 80 is output to the control device 4. In a case where processing liquid lands on the wafer W or in a case where the wafer W is absent in the chamber 20, measurement result of the measurement unit 80 is a minimum value “V0” so as to indicate absence of reflected light from the wafer W. In a case where processing liquid has not landed on the wafer W, measurement result of the measurement unit 80 becomes a value that is greater than the minimum value “V0” so as to indicate presence of reflected light from the wafer W. For example, the measurement unit 80 may be an optical sensor arranged on an inner surface of the chamber 20, which is used for determining presence/absence of the wafer W in the chamber 20.

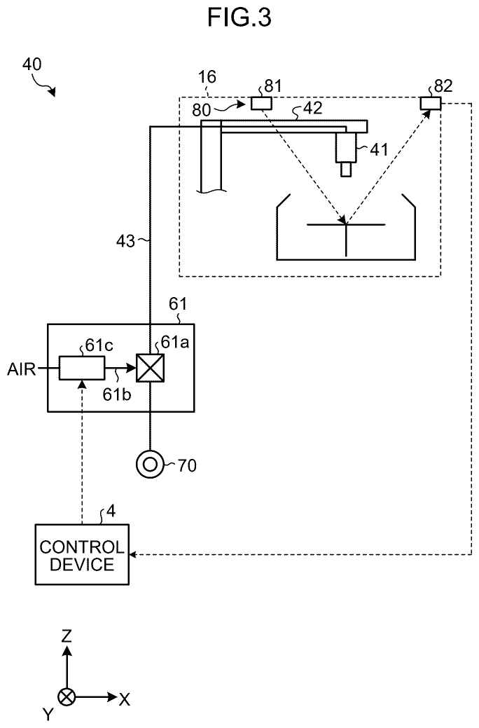

Next, a configuration of the processing fluid supply unit 40 included in the process unit 16 will be explained with reference to FIG. 3. FIG. 3 is a diagram illustrating a configuration example of the processing fluid supply unit 40 according to the first embodiment.

As illustrated in FIG. 3, the processing fluid supply unit 40 includes a nozzle 41 that supplies processing liquid towards the wafer W, a nozzle arm 42 that horizontally supports the nozzle 41, and a turning/lifting mechanism (not illustrated) that turns/lifts the nozzle arm 42.

The processing fluid supply unit 40 includes a supply flow path 43 that connects the nozzle 41 and the processing fluid supply source 70 to each other so as to supply processing liquid supplied from the processing fluid supply source 70 to the nozzle 41.

The supply flow path 43 is a tubular member, and further is formed of a material having a high chemical resistance such as fluororesin. A flow-path opening/closing unit 61 is arranged on the above-mentioned supply flow path 43. The flow-path opening/closing unit 61 opens/closes the supply flow path 43 in accordance with an opening signal and a closing signal output from the control device 4.

The flow-path opening/closing unit 61 includes an air operation valve 61a, an air supplying pipe 61b, and an air adjusting valve 61c. The air operation valve 61a moves a valve body by using pressure of air that is supplied from the air supplying pipe 61b so as to open/close the supply flow path 43. The air adjusting valve 61c is arranged on the air supplying pipe 61b so as to adjust flow volume of air to be supplied to the air operation valve 61a. Specifically, the air adjusting valve 61c adjusts a supply amount of air to the air operation valve 61a so as to execute control such that a valve body of the air operation valve 61a opens/closes at a preliminarily set speed. The air adjusting valve 61c may be referred to as a speed controller.

In a case where receiving an opening signal from the control device 4, the air adjusting valve 61c changes an opened/closed state of the air operation valve 61a from a “closed” state to an “opened” state at a preliminarily-set opening speed. Thus, a valve body of the air operation valve 61a opens at a preliminarily-set set opening speed (in other words, set opening time interval). In a case where receiving a closing signal from the control device 4, the air adjusting valve 61c changes an opened/closed state of the air operation valve 61a from an “opened” state to a “closed” state at a preliminarily-set closing speed. Thus, a valve body of the air operation valve 61a closes at a preliminarily-set set closing speed (in other words, set closing time interval).

The air adjusting valve 61c is preliminarily adjusted so as to close the flow-path opening/closing unit 61 at an appropriate speed. However, for example, in a case where a condition is changed due to long-term usage, exchange of a member, and the like; there presents possibility that the flow-path opening/closing unit 61 (in other words, valve body of air operation valve 61a) is not closed at an appropriate speed so that leakage of processing liquid occurs from the nozzle 41. In a case where leakage of processing liquid occurs from the nozzle 41, the processing liquid adheres to the wafer W due to the liquid leakage so as to cause fluctuation in reflection of light, so that measurement result of the measurement unit 80 fluctuates.

Thus, the substrate processing system 1 according to the first embodiment is configured to monitor presence/absence of leakage of processing liquid from the nozzle 41 on the basis of measurement result of the measurement unit 80 after a closing signal is output to the flow-path opening/closing unit 61. Hereinafter, the above-mentioned point will be specifically explained.

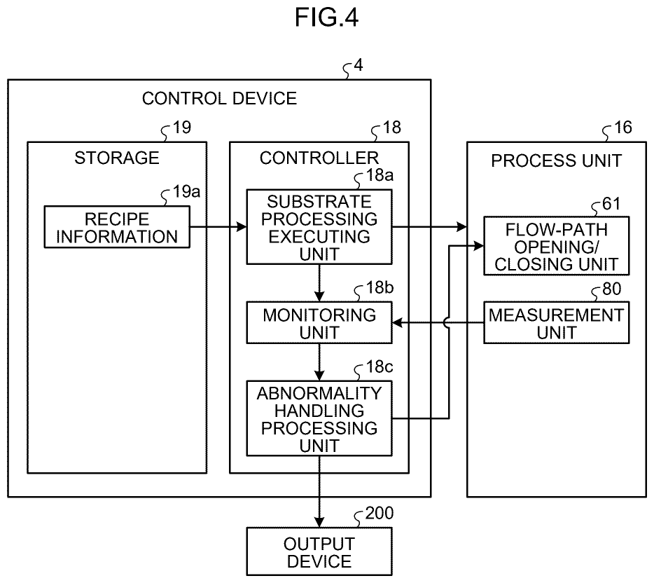

A configuration of the control device 4 will be explained with reference to FIG. 4. FIG. 4 is a block diagram illustrating a configuration example of the control device 4 according to the first embodiment. Note that in FIG. 4, configuration elements necessary for explaining features according to the first embodiment are indicated by using functional blocks so as to omit description of general configuration elements. The illustrated components of the devices illustrated in FIG. 4 are functionally conceptual, and thus they are not to be physically configured as illustrated in the drawings. Specific forms of distribution and integration of the configuration elements of the illustrated devices are not limited to those illustrated in the drawings, and all or some of the devices can be configured by separating or integrating the apparatus functionally or physically in any unit, according to various types of loads, the status of use, etc.

Moreover, all or an arbitrary part of processing functions implemented by each functional block of the control device 4 is realized by a processor such as a Central Processing Unit (CPU), and a program that is analyzed and executed by the processor. Or each of processing functions of the control device 4 may be realized by hardware of Wired Logic.

As illustrated in FIG. 4, the control device 4 includes the controller 18 and the storage 19 (see FIG. 1). For example, the storage 19 is realized by a semiconductor memory element such as a RAM and a Flash Memory, or a storage device such as a hard disk and an optical disk. The above-mentioned storage 19 stores therein recipe information 19a.

The recipe information 19a is information that indicates contents of substrate processing. Specifically, the recipe information 19a is information in which contents of processes to be executed in the process unit 16 during substrate processing are preliminarily registered in the order of a processing sequence.

The controller 18 is a CPU, for example, and reads and executes a not-illustrated program stored in the storage 19 so as to function as functional blocks (substrate processing executing unit 18a, monitoring unit 18b, and abnormality handling processing unit 18c) illustrated in FIG. 4, for example. Note that the above-mentioned program may be recorded in a computer-readable recording medium, and further may be installed in the storage 19 of the control device 4 from the above-mentioned recording medium. The computer-readable recording medium may be, for example, a hard disk (HD), a flexible disk (FD), a compact disk (CD), a magnet-optical disk (MO), a memory card, and the like.

The controller 18 includes the substrate processing executing unit 18a, the monitoring unit 18b, and the abnormality handling processing unit 18c.

In a case where functioning as the substrate processing executing unit 18a, the controller 18 controls the process unit 16 in accordance with the recipe information 19a stored in the storage 19 so as to execute a series of substrate processing. For example, the controller 18 executes a series of substrate processing on the wafer W including chemical liquid processing for supplying chemical liquid, a rinsing process for supplying rinse liquid to the wafer W, and a drying process for increasing the number of rotations of the wafer W so as to dry the wafer W.

The controller 18 outputs an opening signal and a closing signal to the flow-path opening/closing unit 61 of the processing fluid supply unit 40 at a timing according to the recipe information 19a so as to cause the nozzle 41 to discharge processing liquid according to a content of the substrate processing. Processing liquid discharged from the nozzle 41 lands on the wafer W. In this case, the measurement unit 80 measures an intensity of reflected light from the wafer W so as to output measurement result to the controller 18.

In a case where functioning as the monitoring unit 18b, the controller 18 executes a “monitoring process” on the basis of measurement result of the measurement unit 80. The “monitoring process” is a process for monitoring presence/absence of occurrence of leakage of processing liquid from the nozzle 41.

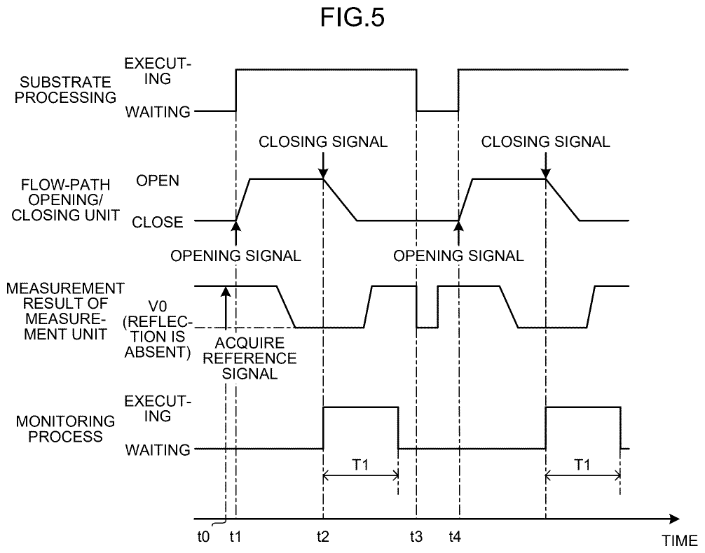

Herein, contents of the monitoring process will be explained with reference to FIG. 5. FIG. 5 is a diagram illustrating an execution timing of a monitoring process according to the first embodiment.

As illustrated in FIG. 5, before starting a series of substrate processing with respect to the wafer W, in other words, before outputting an opening signal to the flow-path opening/closing unit 61, the controller 18 first acquires, as “reference intensity”, an intensity of reflected light that is measured by the measurement unit 80, so as to store it in the storage 19 (see time point t0). At the above-mentioned time point, the flow-path opening/closing unit 61 is in a closed state, and thus processing liquid has not landed on the wafer W yet. In other words, reflection of light from the wafer W is not prevented by processing liquid, and thus an intensity of reflected light stored in the storage 19 as a reference intensity is a value that is greater than a minimum value “V0”.

Next, at a timing for starting a series of substrate processing with respect to the wafer W, the controller 18 outputs an opening signal to the flow-path opening/closing unit 61 (see time point t1). Thus, the flow-path opening/closing unit 61 opens at a preliminarily-set set opening speed so as to start discharge of processing liquid from the nozzle 41. At the above-mentioned time point, processing liquid discharged from the nozzle 41 has not landed on the wafer W yet, and thus measurement result of the measurement unit 80 is kept at a value (>V0) indicating presence of reflected light from the wafer W. A predetermined time interval has elapsed since a time point when an opening signal is output to the flow-path opening/closing unit 61, measurement result of the measurement unit 80 gradually decreases down to a minimum value “V0” indicating absence of reflected light from the wafer W.

Next, the controller 18 outputs a closing signal to the flow-path opening/closing unit 61 (see time point t2). Thus, the flow-path opening/closing unit 61 closes at a preliminarily-set closing speed, so as to stop discharging of processing liquid from the nozzle 41. At the above-mentioned time point, the processing liquid is remaining on the wafer, and thus measurement result of the measurement unit 80 is kept at a minimum value “V0” indicating absence of reflected light from the wafer W. A predetermined time interval has elapsed since a time point when an opening signal is output to the flow-path opening/closing unit 61, measurement result of the measurement unit 80 gradually increases up to the reference intensity from the minimum value “V0”.

A monitoring process is executed during a predetermined time period T1 starting from a time point when a closing signal is output to the flow-path opening/closing unit 61. A length of the predetermined time period T1 is set to a length that is longer than an expected time interval from a time when an closing signal is output until a time when the flow-path opening/closing unit 61 is completely closed so that an intensity of reflected light from the wafer W reaches the reference intensity.

In the monitoring process, the controller 18 monitors presence/absence of leakage of processing liquid from the nozzle 41 on the basis of an intensity of reflected light that is measured by the measurement unit 80 after output of a closing signal.

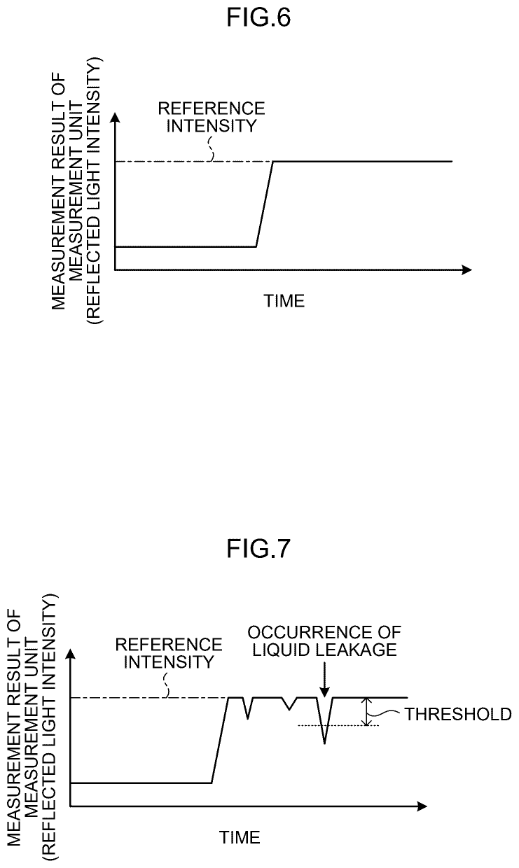

A monitoring process of presence/absence of liquid leakage based on an intensity of reflected light will be specifically explained with reference to FIG. 6 and FIG. 7. FIG. 6 is a diagram illustrating one example of measurement result of the measurement unit 80 in a case where leakage of processing liquid from the nozzle 41 has not occurred. FIG. 7 is a diagram illustrating one example of measurement result of the measurement unit 80 in a case where leakage of the processing liquid from the nozzle 41 has occurred.

As illustrated in FIG. 6, in a case where liquid leakage has not occurred, a change in a reflected light intensity from a reference intensity is not found in measurement result of the measurement unit 80 after reaching the reference intensity.

On the other hand, as illustrated in FIG. 7, in a case where liquid leakage has occurred, a change in a reflected light intensity, which is greater than that in a case where liquid leakage has not occurred, is found in measurement result of the measurement unit 80 after reaching the reference intensity.

Thus, the controller 18 determines whether or not a change amount from the reference intensity of an intensity of reflected light exceeds a threshold, which is measured by the measurement unit 80, during the predetermined time period T1 after outputting a closing signal. In a case where the change amount exceeds the threshold, the controller 18 detects occurrence of leakage of processing liquid.

As described above, monitoring is executed on the basis of an intensity of reflected light to be capable of appropriately capturing a change point of the reflected light intensity in a case where liquid leakage has occurred, so that it is possible to detect abnormality related to liquid leakage with high accuracy.

Additionally, a measurement period of an intensity of reflected light is shorter than a capturing period of a captured image by an infrared camara. Therefore, by employing monitoring based on an intensity of reflected light, it is possible to detect instant liquid leakage that is not captured by monitoring based on a captured image by an infrared camara, such as tiny fluctuation of a liquid surface on the wafer W.

Note that in FIG. 7, liquid leakage is detected on the basis of a change amount in an intensity of reflected light from a reference intensity; however, liquid leakage may be detected by using an intensity of reflected light alone without using a reference intensity. For example, the controller 18 may compare a first intensity of reflected light, which is measured at a first time point during the predetermined time period T1 after outputting an closing signal, with a second intensity of the reflected light that is measured at a second time point after the first time point, so as to detect occurrence of liquid leakage in a case where a change amount in the second intensity from the first intensity exceeds a threshold.

The controller 18 may detect operation abnormality in the flow-path opening/closing unit 61 on the basis of an elapsed time interval from a time when outputting a closing signal to the flow-path opening/closing unit 61 until a time when an intensity of reflected light reaches a reference intensity.

In other words, the controller 18 determines whether or not the elapsed time interval exceeds the threshold. In a case where the elapsed time interval exceeds the threshold, the controller 18 detects operation abnormality in the flow-path opening/closing unit 61. Thus, it is possible to detect operation abnormality in the flow-path opening/closing unit 61 in addition to liquid leakage.

In a case where the predetermined time period T1 has elapsed, and further a predetermined time interval has elapsed, substrate processing with respect to the first wafer W ends (see time point t3). During a time period from the time point t3 until a time point t4, the first wafer W is carried out of the chamber 20, and the next wafer W is carried into the chamber 20. In a case where the first wafer W is carried out of the chamber 20, the wafer W is absent in the chamber 20, and thus measurement result of the measurement unit 80 becomes a minimum value “V0” so as to indicate absence of reflected light from the wafer W. Next, in a case where the wafer W is carried into the chamber 20, the wafer W is present in the chamber 20, and thus measurement result of the measurement unit 80 becomes a value that is greater than a minimum value “V0” so as to indicate presence of reflected light from the wafer W.

Next, at a timing when starting substrate processing on the next wafer W, the controller 18 outputs an opening signal to the flow-path opening/closing unit 61 again (see time point t4). After the time point t4, substrate processing is executed on the next wafer W.

Returning to FIG. 4, the abnormality handling processing unit 18c will be explained. In a case where detecting abnormality in the monitoring process, the controller 18 functions as the abnormality handling processing unit 18c so as to execute a predetermined abnormality handling process.

For example, the controller 18 causes an output device 200, such as a display unit and a sound outputting unit, to output warning information such as a warning screen and a warning sound. Thus, it is possible to cause an operator to recognize occurrence of abnormality.

The controller 18 interrupts the presently-executing substrate processing. Thus, for example, it is possible to avoid a case where leakage of processing liquid occurs in the next substrate processing and the like, and leaked processing liquid adheres to the wafer W so as to cause product defect.

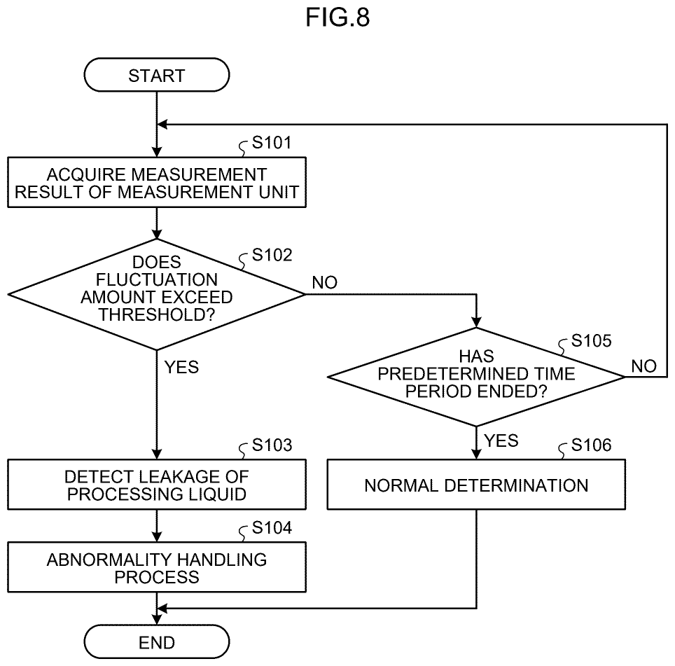

Next, a procedure for the above-mentioned monitoring process will explained with reference to FIG. 8. FIG. 8 is a flowchart illustrating a procedure for the monitoring process according to the first embodiment.

As illustrated in FIG. 8, in a case where the predetermined time period T1 (see FIG. 5) starts, the controller 18 acquires measurement result of the measurement unit 80 (Step S101), and further determines whether or not a fluctuation amount from a reference intensity in an intensity of reflected light in the acquired measurement result exceeds a threshold (Step S102).

In a case where determining that a fluctuation amount from a reference intensity in an intensity of reflected light exceeds a threshold (Step S102: Yes), the controller 18 detects leakage of processing liquid from the nozzle 41 (Step S103), and further executes an abnormality handling process (Step S104). For example, the controller 18 interrupts substrate processing, and further outputs warning information to the output device 200.

In a case where determining that a fluctuation amount from a reference intensity in an intensity of reflected light does not exceed a threshold in Step S102 (Step S102: No), the controller 18 determines whether or not the predetermined time period T1 has ended (Step S105). In a case where the predetermined time period T1 has not ended (Step S105: No), the controller 18 returns the processing to Step S101 so as to repeat processes of Steps S101 to S102 and Step S105.

On the other hand, in a case where the predetermined time period T1 has ended (Step S105: Yes), the controller 18 executes normal determination that leakage of processing liquid from the nozzle 41 has not occurred (Step S106). In a case where a process of Step S104 or Step S106 has ended, the controller 18 ends the monitoring process.

As described above, a substrate processing apparatus (for one example, substrate processing system 1) according to the first embodiment includes a chamber (for one example, chamber 20), a nozzle (for one example, nozzle 41), a measurement unit (for one example, measurement unit 80), a flow-path opening/closing unit (for one example, flow-path opening/closing unit 61), and a controller (for one example, controller 18). The chamber is capable of housing therein a substrate (for one example, wafer W). The nozzle is arranged in the chamber to supply processing liquid towards the substrate. The measurement unit projects light to the substrate to measure an intensity of reflected light from the substrate. The flow-path opening/closing unit opens/closes a supply flow path (for one example, supply flow path 43) of the processing liquid to the nozzle. The controller is configured to output an opening signal and a closing signal to the flow-path opening/closing unit, the opening signal causing the flow-path opening/closing unit to execute an opening operation for opening the supply flow path, and the closing signal causing the flow-path opening/closing unit to execute an closing operation for closing the supply flow path. The controller is further configured to detect abnormality related to leakage of the processing liquid from the nozzle based on the intensity of reflected light that is measured by the measurement unit after an output of the closing signal.

Therefore, in accordance with the substrate processing apparatus according to the first embodiment, it is possible to detect abnormality related to liquid leakage with high accuracy.

Note that in the above-mentioned first embodiment, it is preferable that the nozzle 41 supply processing liquid towards the wafer W from the above of the wafer W. Moreover, it is further preferable that processing liquid be supplied from the nozzle 41 during a time period when the wafer W is rotating.

### Second Embodiment

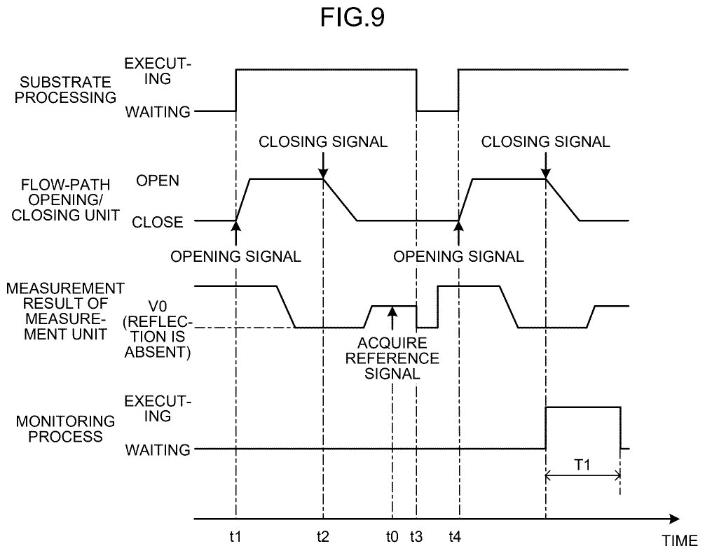

In a second embodiment, an acquisition timing of a reference intensity and an execution timing of a monitoring process are different from those according to the first embodiment. FIG. 9 is a diagram illustrating an acquisition timing of a reference intensity and an execution timing of a monitoring process according to the second embodiment.

Herein, as substrate processing, substrate processing for changing a surface state of the wafer W by using processing liquid is executed in some cases. The surface state of the wafer W indicates a shape and/or a color thereof, for example. The substrate processing for changing a surface state of the wafer W by using processing liquid indicates an etching process and/or a film forming process, for example. In the above-mentioned substrate processing, an intensity of reflected light from the wafer W changes in some cases before and after change in a surface state of the wafer W.

Thus, in the substrate processing with respect to the first wafer W, the controller 18 acquires, as “reference intensity”, an intensity of reflected light at a time point when measurement result of the measurement unit 80 has converged within a predetermined range after outputting an closing signal to the flow-path opening/closing unit 61, and further stores it in the storage 19 (see time interval t0).

As described above, an intensity of reflected light is acquired at a time point when measurement result of the measurement unit 80 has converged within a predetermined range after outputting a closing signal, so that it is possible to grasp an intensity of reflected light after change in a surface state of the wafer W.

In the present embodiment, in substrate processing with respect to the next wafer W, a monitoring process is executed during the predetermined time period T1 from a time point when a closing signal is output to the flow-path opening/closing unit 61 again. Contents of the above-mentioned monitoring process are the same or similar to those having been explained with reference to FIG. 6 and FIG. 7.

As described above, in the second embodiment, an intensity of reflected light at a time point when measurement result of the measurement unit 80 has converged within a predetermined range after outputting an closing signal is acquired as a reference intensity. Thus, even in a case where an intensity of reflected light from the wafer W changes before and after change in a surface state of the wafer W, it is possible to detect abnormality related to liquid leakage by using a reference intensity with high accuracy.

### Third Embodiment

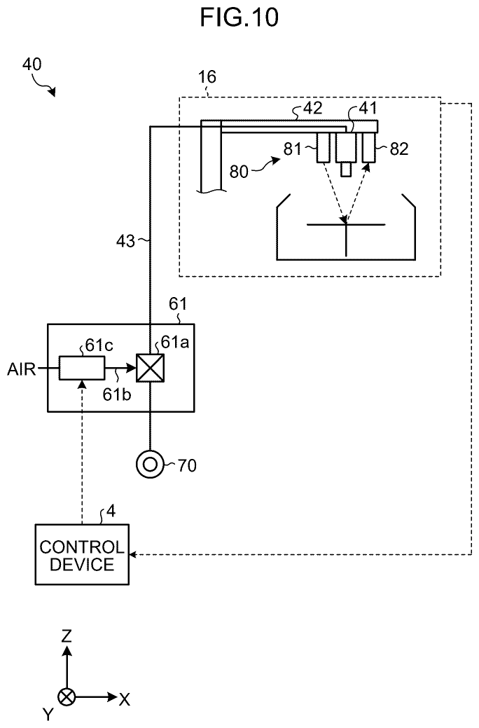

In a third embodiment, arrangement of the measurement unit 80 is different from that according to the first embodiment. FIG. 10 is a diagram illustrating a configuration example of the processing fluid supply unit 40 according to the third embodiment.

As illustrated in FIG. 10, the processing fluid supply unit 40 according to the third embodiment includes the nozzle 41 that supplies processing liquid towards the wafer W, the nozzle arm 42 that horizontally supports the nozzle 41, and a turning/lifting mechanism (not illustrated) that turns and lifts the nozzle arm 42.

In the third embodiment, the measurement unit 80 is arranged on the nozzle arm 42. The measurement unit 80 includes the light projecting unit 81 and the light receiving unit 82 so as to project light from the nozzle arm 42 towards the wafer W and further to measure an intensity of reflected light from the wafer W.

As described above, the measurement unit 80 is arranged on the nozzle arm 42, so that it is possible to move a projecting position of light emitted from the measurement unit 80 towards the wafer W close to a liquid-landing position of processing liquid discharged from the nozzle 41 towards the wafer W. Therefore, it is possible to shorten a time lag from a time point when light is projected from the light projecting unit 81 of the measurement unit 80 towards a liquid-landing position on the wafer W until a time point when reflected light from the liquid-landing position on the wafer W received by the light receiving unit 82. As a result, a change point in a reflected light intensity in a case where liquid leakage has occurred can be appropriately captured, so that it is possible to detect abnormality related to instant liquid leakage with high accuracy.

Note that in FIG. 10, a case is exemplified in which the measurement unit 80 is arranged on the nozzle arm 42; however, an arrangement position of the measurement unit 80 is not limited to one illustrated in FIG. 10. For example, the measurement unit 80 may be arranged on the nozzle 41. In this case, the measurement unit 80 projects light from the nozzle 41 towards the wafer W so as to measure an intensity of reflected light from the wafer W. Thus, it is possible to more shorten a time lag from a time point when light is projected from the light projecting unit 81 of the measurement unit 80 towards a liquid-landing position on the wafer W until reflected light from the liquid-landing position on the wafer W is received by the light receiving unit 82.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A substrate processing apparatus comprising:
a chamber that is capable of housing therein a substrate;
a nozzle that is arranged in the chamber to supply processing liquid towards the substrate;
a measurement unit that projects light to the substrate to measure an intensity of reflected light from the substrate;
a flow-path opening/closing unit that opens/closes a supply flow path of the processing liquid to the nozzle;
a controller that is configured to output an opening signal and a closing signal to the flow-path opening/closing unit, the opening signal causing the flow-path opening/closing unit to execute an opening operation for opening the supply flow path, and the closing signal causing the flow-path opening/closing unit to execute a closing operation for closing the supply flow path, wherein
the controller is further configured to:
detect abnormality related to leakage of the processing liquid from the nozzle based on the intensity of reflected light that is measured by the measurement unit after an output of the closing signal.

2. The substrate processing apparatus according to claim 1, wherein
the controller that is further configured to:
detect abnormality related to leakage of the processing liquid from the nozzle based on a change amount from a reference intensity in the intensity of reflected light that is measured by the measurement unit after the output of the closing signal.

3. The substrate processing apparatus according to claim 2 further comprising:
a storage, wherein
the controller that is further configured to:
acquire, as the reference intensity, the intensity of reflected light that is measured by the measurement unit before the output of the opening signal;
store the acquired intensity of reflected light in the storage; and
detect abnormality related to leakage of the processing liquid from the nozzle based on a fluctuation amount from the acquired reference intensity in the intensity of reflected light which is measured by the measurement unit after the output of the closing signal.

4. The substrate processing apparatus according to claim 2 further comprising:
a storage, wherein
the controller is further configured to:
in substrate processing with respect to the substrate, acquire, as the reference intensity, an intensity of the reflected light at a time point when an intensity of the reflected light that is measured by the measurement unit after the output of the closing signal has converged within a predetermined range;
store the acquired intensity of the reflected light in the storage; and
in substrate processing with respect to a next substrate, detect abnormality related to leakage of the processing liquid from the nozzle based on a fluctuation amount from the acquired reference intensity in the intensity of reflected light which is measured by the measurement unit after the output of the closing signal.

5. The substrate processing apparatus according to claim 2, wherein
the controller is further configured to:
detect operation abnormality in the flow-path opening/closing unit based on an elapsed time interval from a time point when the closing signal is output to the flow-path opening/closing unit until a time point when the intensity of reflected light reaches the reference intensity.

6. The substrate processing apparatus according to claim 1, wherein
the measurement unit includes an optical sensor that is arranged on an inner surface of the chamber to be used for determining presence/absence of the substrate in the chamber.

7. The substrate processing apparatus according to claim 1, wherein
the measurement unit is arranged on one of the nozzle and a nozzle arm that supports the nozzle to be configured to:
project light towards the substrate from the one of the nozzle and the nozzle arm; and
measure an intensity of reflected light from the substrate.

8. An abnormality detecting method to be used by a substrate processing apparatus comprising: a chamber that is capable of housing therein a substrate; a nozzle that is arranged in the chamber to supply processing liquid towards the substrate; a measurement unit that projects light to the substrate to measure an intensity of reflected light from the substrate; and a flow-path opening/closing unit that opens/closes a supply flow path of the processing liquid to the nozzle, the method comprising:
outputting an opening signal and a closing signal to the flow-path opening/closing unit, the opening signal causing the flow-path opening/closing unit to execute an opening operation for opening the supply flow path, and the closing signal causing the flow-path opening/closing unit to execute an closing operation for closing the supply flow path; and
detecting abnormality related to leakage of the processing liquid from the nozzle based on the intensity of reflected light that is measured by the measurement unit after an output of the closing signal.
